(19) United States
(12) Patent Application Publication
(10) Pub. No.: US 2008/0210457 A1
(43) Pub. Date: Sep. 4, 2008

(54) Tape carrier for semiconductor device and method for making same

(75) Inventors: Hiroaki Hiratsuka, Hitachi (JP); Hiroshi Ishikawa, Hitachi (JP); Masaaki Tsutsumida, Hitachi (JP)

Correspondence Address: FOLEY AND LARDNER LLP;SUITE 500, 3000 K STREET NW, WASHINGTON, DC, 20007, US

(73) Assignee: HITACHI CABLE, LTD.

(21) Appl. No.: 12/000,575

(22) Filed: Dec. 13, 2007

(30) Foreign Application Priority Data
Dec. 14, 2006 (JP) 2006-337181
Oct. 25, 2007 (JP) 2007-277529

(51) Int. Cl. H05K 1/03; H05K 3/06

(52) U.S. Cl. 174/254; 29/847

(57) ABSTRACT

A tape carrier for semiconductor device has a resin tape provided with an opening section for bonding, and a wiring lead formed on the resin tape. The wiring lead has a notched section disposed in the opening section and including a notch width W_{N}, and a lead width W_{L} at a position where a bonding tool contacts the wiring lead, and a ratio of the notch width W_{N} to the lead width W_{L} is more than 0.5 and less than 0.685. A method for making the tape carrier includes laminating the metal foil on one surface of the resin tape including the opening section for bonding, and forming the wiring lead in the metal foil by photolithography such that the wiring lead has the notched section disposed in the opening section and including the notch width W_{N}, and the lead width W_{L} at the position where the bonding tool contacts the wiring lead.

The present application is based on Japanese patent application Nos. 2006-337181-2007-277529 filed on Dec. 14, 2006 and Oct. 25, 2007, respectively, the entire contents of which are incorporated herein by reference.

### BACKGROUND OF THE INVENTION

1. Field of the Invention

The invention relates to a tape carrier for a package type semiconductor device, and a method for making the same.

2. Description of the Related Art

A BGA (Ball Grid Array) package type semiconductor device which is surface-mounted on a printed-circuit board through a solder ball can be electrically connected with the printed-circuit board by using the whole surface of a flat portion of the package. Thus, the BGA package type is advantageous in that the number of pins (terminals) can be easy to increase without narrowing a pitch between terminals (leads) as compared to a semiconductor device in the form of QFP (Quad Flat Package) or the like where electrical connection is made through outer leads at respective sides of the package.

Some BGA package type semiconductor devices use a TAB (Tape Automated Bonding) tape as a package structural material. The BGA package using the TAB tape is suited to be low-profiled and downsized, and it can be used for a CSP (Chip Size Package) such as μBGA (registered trade mark of US Tessera Corporation).

The μBGA package belongs to a tape BGA type of CSP and is constructed such that an elastomer (low elasticity resin) is disposed between a semiconductor chip and a TAB tape, and the semiconductor chip is connected through an S or J-shaped lead to the TAB tape (See JP-A-2005-101638, and JP-A-H10-506235). Since the μBGA package is provided with the elastomer, thermal stress generated between the package and the printed-circuit board can be reduced by the elastomer to extend the lifetime of solder ball joints.

The connection of the TAB tape to the semiconductor chip is conducted such that a wiring lead formed on the TAB tape is positioned to an electrode pad of the semiconductor chip, and a bonding tool is pressed down from above the wiring lead to cut the wring lead, where a cut end of the wiring lead is bonded to the electrode pad by the pressing of the bonding tool.

In order to facilitate the cutting of the wiring lead when pressing down the wiring lead by the bonding tool to cut the wiring lead and to bond the wiring lead to the electrode pad, JP-A-H10-41344 and JP-A-H10-41345 disclose a tape carrier for semiconductor device with a wiring lead that has a notched portion with a width smaller than that of the wiring lead at a predetermined position where the wiring lead is cut down by the bonding tool to be bonded to the electrode pad.

However, in the conventional tape carrier for semiconductor device with the above wiring lead, a problem arises that, if the constriction of the notched portion is insufficient relative to the width of the lead, the wiring lead may be cut down at an undesired position other than the predetermined position, or the wiring lead may not be cut down at all. As a result, a bonding failure will be caused between the tape carrier for semiconductor and the semiconductor chip, where yield in mounting process lowers.

### SUMMARY OF THE INVENTION

Accordingly, it is an object of the invention to provide a carrier tape for semiconductor device and a method for making the same that can prevent the incidence an uncut lead when bonding an inner lead thereof so as to secure the stable inner lead bonding.

(1) According to one embodiment of the invention, a tape carrier for semiconductor device comprises:

a resin tape provided with an opening section for bonding; and

a wiring lead formed on the resin tape,

wherein the wiring lead comprises a notched section disposed in the opening section and including a notch width W_{N}, and a lead width W_{L} at a position where a bonding tool contacts the wiring lead, and

a ratio (W_{N}/W_{L}) of the notch width W_{N} to the lead width W_{L} is more than 0.5 and less than 0.685.

According to another embodiment of the invention, a method for making a tape carrier for semiconductor device comprises:

laminating a metal foil on one surface of a resin tape provided with an opening section for bonding; and

forming a wiring lead in the metal foil by photolithography such that the wiring lead comprises a notched section disposed in the opening section and including a notch width W_{N}, and a lead width W_{L} at a position where a bonding tool contacts the wiring lead,

wherein a ratio (W_{N}/W_{L}) of the notch width W_{N} to the lead width W_{L} is more than 0.5 and less than 0.685.

### BRIEF DESCRIPTION OF THE DRAWINGS

The invention will be explained in more detail in conjunction with appended drawings, wherein:

FIG. 1A is a plan view showing a carrier tape for semiconductor device according to the exemplary embodiment of the invention;

FIG. 1B is a cross sectional view of a part of the carrier tape for semiconductor device in FIG. 1A;

FIG. 2 is a partially enlarged view showing an opening section of a resin tape;

FIGS. 3A to 3G are cross sectional views showing steps for making the carrier tape for semiconductor device according to the exemplary embodiment of the invention;

FIGS. 4A and 4B are cross sectional views showing the bonding of a tape carrier for semiconductor according to the invention to a semiconductor chip, where FIG. 4A shows a state prior to the bonding, and FIG. 4B shows the bonding of a wiring lead to an electrode pad; and

FIG. 5 is a graph showing an experimental result of “incidence rate of uncut lead vs. ratio of notch width to lead width” when bonding a wiring lead.

### DESCRIPTION OF THE PREFERRED EMBODIMENTS

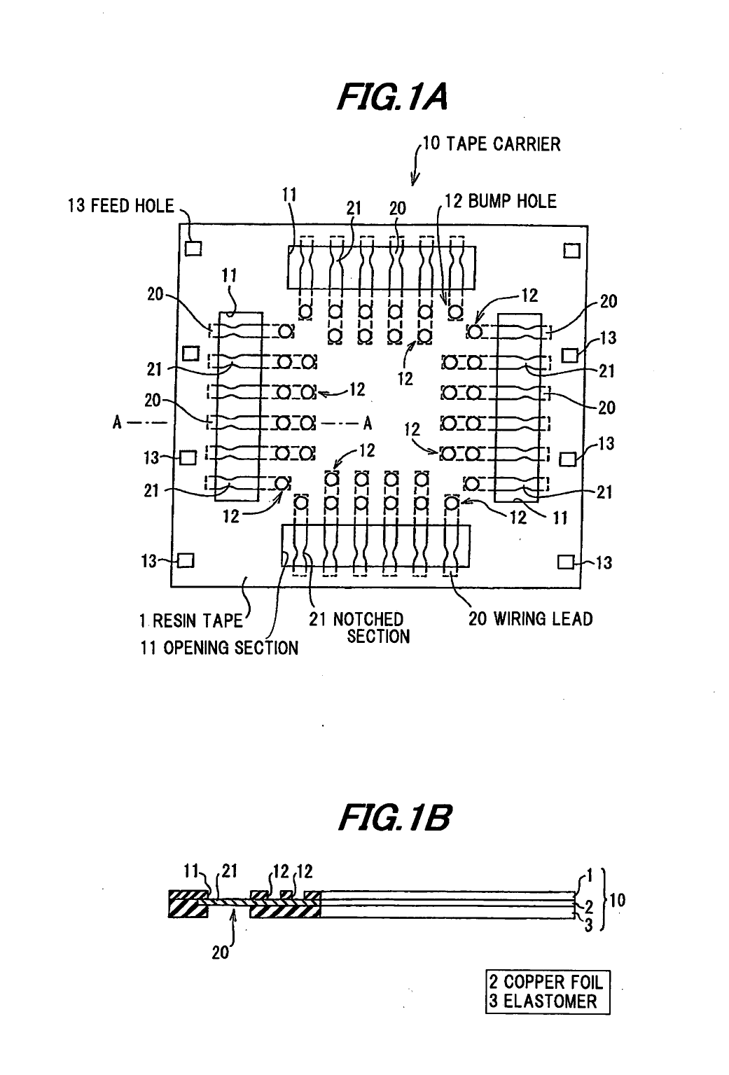

FIG. 1A is a plan view showing a carrier tape for semiconductor device according to the exemplary embodiment of the invention. FIG. 1B is a cross sectional view of a part of the carrier tape for semiconductor device cut along a line A-A in FIG. 1A.

The carrier tape for semiconductor device 10 includes a resin tape 1 made of a polyimide resin film wherein an adhesive is applied on either surface of the resin film, and a copper foil 2 made of a standard electrolytic copper foil and which is bonded to the resin tape 1 with the adhesive. An elastomer 3 being a low elastic resin material is bonded to the surface of the side of the resin tape 1 to which the copper foil 2 is provided through an adhesive (not shown). In the exemplary embodiment, 3EC-HTE manufactured by Mitsui Mining & Smelting Co., Ltd. is used as an electrolytic copper foil.

The resin tape 1 has an opening section 11 as a bonding window for bonding a wiring lead 20 formed from the copper foil 2 shown in FIG. 1B to the terminal electrode (electrode pad) of a semiconductor chip, bump holes 12 for connecting electrically bumps with the wiring leads 20, and feed holes 13 for conveying a tape carrier.

The copper foil 2 is formed in the wiring pattern in response to the terminal configuration of a semiconductor chip and exposed so as to traverse the opening section 11 formed in a rectangular shape in the resin tape 1, and further, the copper foil has a plurality of the wiring leads 20 aligned parallel in a distance with each other. A notched section 21 having a smaller width than that of the other part of a wiring lead 20 is formed so as to be fractured in the case that the wiring lead 20 is bonded to the electrode pad of a semiconductor chip by means of a bonding tool.

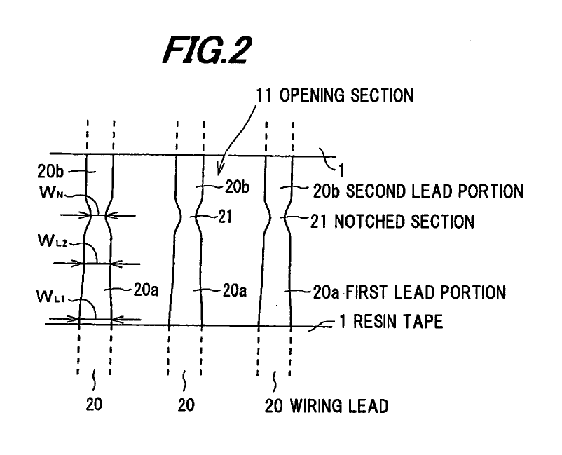

FIG. 2 is a partially enlarged view showing the opening section 11 of the resin tape 1 wherein the wiring lead 20 has a uniform thickness of 18 μm in which a first lead portion 20a provided for connecting bumps to form an inner lead is linked to a second lead portion 20b through the notched section 21. The width W_{N} of the notched section 21 formed in a curved constricted shape is defined so as to be smaller than the width W_{L1} of the first lead portion 20a and the width W_{L2} of the second lead portion 20b (W_{L2}<W_{L1}).

The notch width W_{N} of the notched section 21 is set to be W_{N}<W_{L1}, and the notched section 21 is formed such that the ratio of the notch width W_{N} to the lead width W_{L1} (W_{N}/W_{L1}) is less than 0.685. If the wiring lead 20 used has a different thickness from 18 μm, the ratio of the notch width W_{N} to the lead width W_{L1} can be adjusted according to the difference from 18 μm. On the other hand, if the lead width of the wiring lead 20 is the same along its entire length (i.e., W_{L1}=W_{L2}), the lead width W_{L2} where the tip of a bonding tool contacts the wiring lead 20 is used to calculate the ratio W_{N}/W_{L} (i.e., W_{N}/W_{L2}).

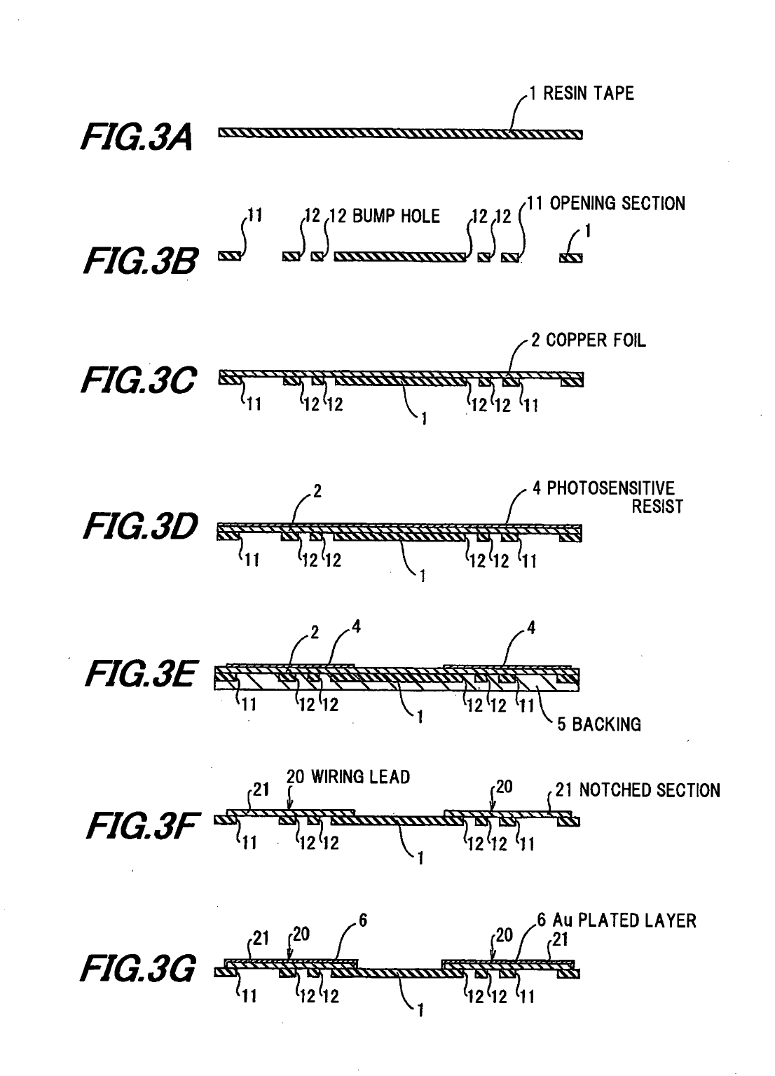

FIGS. 3A to 3G are cross sectional views showing the steps of making the tape carrier for semiconductor device according to the exemplary embodiment of the invention. At first, the resin tape 1 made of a polyimide resin film on either surface of which an adhesive is applied is prepared in a resin tape preparation step as shown in FIG. 3A.

Then, the opening sections 11, bump holes 12, and conveying feed holes (not shown) are punched to be formed by means of a pressing machine in a press working step as shown in FIG. 3B.

Then, the copper foil 2 being a metal foil is bonded to the resin tape 1 in accordance with a lamination working to fabricate a tape material in a copper foil lamination step as shown in FIG. 3C.

Then, a liquid or solid photosensitive resist 4 is applied or laminated onto the surface of the copper foil 2 of the tape material formed in the copper foil lamination step in a resist formation step as shown in FIG. 3D.

Then, the copper foil 2 is patterned by practicing exposure and development on the surface of the copper foil 2 on which the photosensitive resist 4 is applied in accordance with photolithography and in this case, a backing 5 is applied on the undersurface (bump formation surface) of the resin tape 1 as well as inside the opening section 11 in a development/backing step as shown in FIG. 3E.

Then, the copper foil 2 is etched, and then, the photosensitive resist 4 is peeled off to form the wiring leads 20 of a predetermined pattern, whereby the wiring leads 20 having the notched sections 21 are formed so as to expose inside the opening section 11 in an etching step as shown in FIG. 3F.

Finally, an Au plated layer 6 is provided on the surface of the copper foil 2 in order to make better the connection with the electrode pad of a semiconductor chip in a plating step as shown in FIG. 3G.

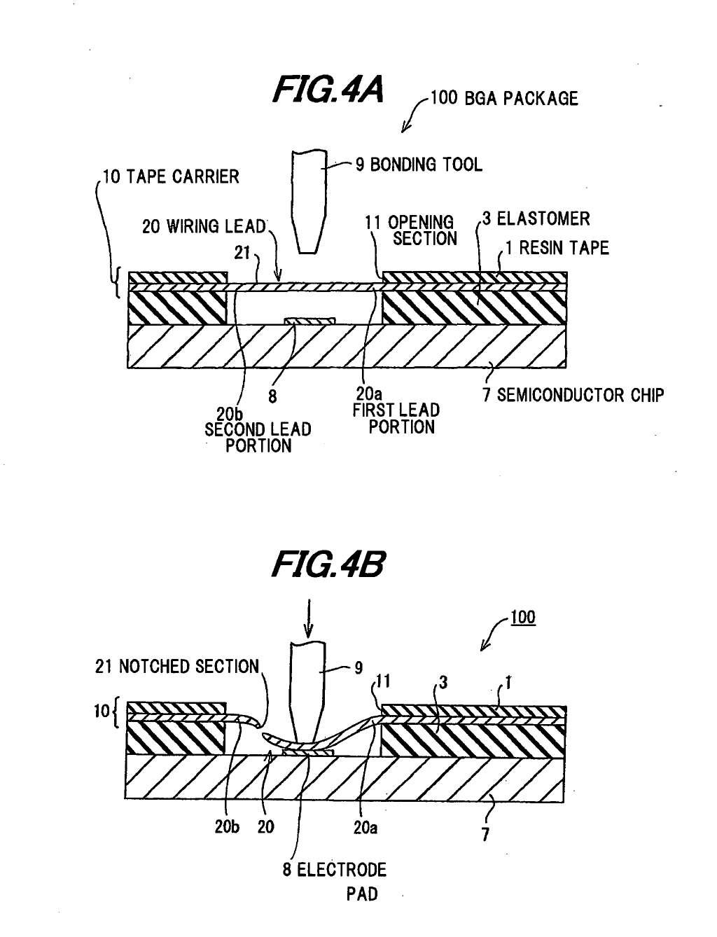

FIGS. 4A and 4B are cross sectional views showing steps for bonding the tape carrier for semiconductor device of the invention to a semiconductor chip, where FIG. 4A is a view showing the condition prior to bonding, and FIG. 4B is a view showing a bonding operation with respect to an electrode pad. In this case, the bonding with respect to the electrode pad in a BGA package by using the tape carrier for semiconductor device of the invention will be described.

A BGA package 100 is a CSP of a BGA type tape, and it is a μBGA package wherein the elastomer 3 is disposed between the semiconductor chip 7 and the tape carrier for semiconductor device 10, and the wiring lead 20 of the tape carrier for semiconductor device 10 is electrically connected with the electrode pad 8.

First, as shown in FIG. 4A, the semiconductor chip 7 is joined to the tape carrier for semiconductor device 10 through the elastomer 3 wherein the wiring lead 20 is suspended horizontally so as to be exposed in the opening section 11. The bonding tool 9 is located at the position where the electrode pad 8 is disposed through the wiring lead 20.

Then, as shown in FIG. 4B, when the bonding tool 9 located at the position over the electrode pad 8 is lowered, the bonding tool 9 is in contact with the first lead portion 20a, and when the contact portion is further lowered, the wiring lead 20 is fractured in the constricted portion of the notched section 21. Consequently, the extreme end of the first lead portion 20a is pressure-bonded to the electrode pad 8 by means of the bonding tool 9, whereby the bonding between the first lead portion 20a and the electrode pad 8 is completed. On the other hand, the second lead portion 20b is left on the side of the resin tape 1.

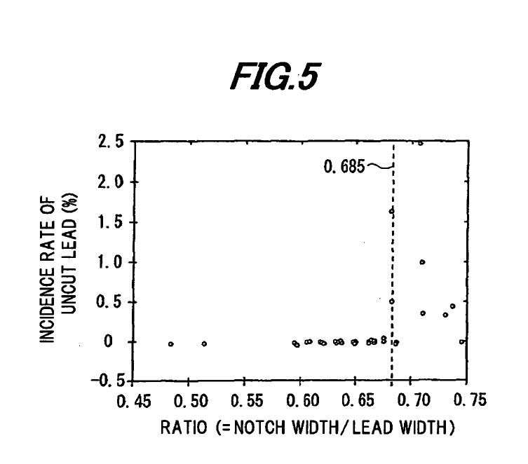

FIG. 5 is a graph showing an experimental result of “incidence rate of uncut lead vs. ratio of notch width to lead width” when bonding a wiring lead, where the wiring lead 20 with a thickness of 18 μm is used. Conventionally, the ratio is preferably 0.5. However, as is clear from FIG. 5, it is conformed that the incidence rate (%) of uncut failure of the wiring lead 20 is substantially zero just before the ratio reaches 0.685, and consequently, no problem arises even when the ratio exceeds the conventional one, 0.5. Thus, since the ratio may be close to 0.685, given that the notch width W_{N} is the same as that of the conventional one, the lead width W_{L1} of the wiring lead 20 can be narrower than that used when the ratio is conventionally 0.5.

As the notch width W_{N} of the notched section 21 decreases, the incidence rate of a failure such as deformation in the wiring lead 20 exposed inside the opening section 11 will increase. However, in case of the embodiment, the ratio of the notch width W_{N} to the lead width W_{L1} can be increased up to nearly 0.685, so that it becomes possible to reduce by about 30% the lead width W_{L1} as compared to the conventional lead width without changing the notch width W_{N}. As a consequence, it becomes possible to provide a TAB tape for semiconductor device which is excellent in productivity, high in integration density, and downsized. From this viewpoint, the ratio (W_{N}/W_{L1}) is desirably in the range not less than 0.6 and less than 0.685 and more desirably closer to 0.685.

The reason for using the lead width W_{L1} close to a mounting region for a semiconductor device (e.g., a chip) in calculating the ratio will be described below.

As shown in FIG. 4B, when the wiring lead 20 is bonded to the electrode pad 8 by using the bonding tool 9, load caused by the bonding tool 9 is maximized at a position (i.e., at around the first lead portion 20a with the lead width W_{L1}) of the wiring lead 20 close to the mounting region inside the opening section 11. Therefore, the lead width W_{L1} is used to calculate the ratio.

Different from the shape of the wiring lead 20 as shown in FIG. 2, if the lead width W_{L2} where the bonding tool 9 contacts the wiring lead 20 is wider than the lead width W_{L1} (i.e., W_{L2}>W_{L1}), the lead width W_{L1} is used as the lead width W_{L} to calculate the ratio. Thereby, it can be avoided that the wiring lead 20 is not cut down at all, or cut down at an undesired position.

### Effects of the Embodiment

In the above embodiment, the following advantageous effects can be obtained.

(1) Since the ratio of the notch width W_{N} to the lead width W_{L1} (W_{N}/W_{L1}) in the wiring lead 20 can be increased up to nearly 0.685, it becomes possible to have the lead width W_{L1} (or W_{L2}) smaller than before, without changing the notch width W_{N}. Even in this case, the failure such as deformation in the wiring lead 20 exposed inside the opening section 11 can be prevented since the notch width W_{N} is unchanged. Thus, the tape carrier for semiconductor device of the embodiment can be produced at high yield.
(2) Since the ratio (W_{N}/W_{L1}) can be increased up to nearly 0.685, it becomes possible to reduce by about 30% the lead width W_{L1} than before without changing the notch width W_{N}. Thus, the distance between the wiring leads 20 can be reduced so that the tape carrier for semiconductor device of the embodiment can provide for a downsized tape BGA package with high integration density.

In the above exemplary embodiment, the commercially available standard electrolytic copper foil is used as the copper foil. Since commercially available standard electrolytic copper foils are all made of pure copper, the basic properties such as tensile strength, and elongation based on the composition are substantially the same, although some properties such as surface roughness depend on the manufacturer. In the range confirmed by the inventor(s), industrially substantially the same or equal effects are obtained in the case that any of electrolytic copper foils having the surface roughness of the same degree is used, so far as the above-mentioned ratio close to 0.685 is satisfied. Furthermore, the easiness in fracture of a lead relates to the elongation percentage thereof, and the higher elongation percentage results in the more difficult fracture. However, even when a copper foil having a rather higher elongation percentage of 25% at 180° C. is used, industrially substantially the same or equal effects are obtained so far as the above-mentioned ratio close to 0.685 is satisfied. In a rolled copper foil, since orientation can be caused by the rolling, the value, 0.685, may be changed depending on the orientation.

### Other Embodiments

The invention is not limited to the above exemplary embodiments, but a variety of modifications may be made within a range where the subject matter thereof is not changed.

In the above embodiment, the wiring lead 20 exposed inside the opening section 11 has the lead width W_{L1} at a position (i.e., at around the first lead portion 20a) close to the mounting region for a semiconductor device is formed a little wider than the lead width W_{L2} close to the notched section 21. However, the invention is not limited thereto, and W_{L1}=W_{L2} may be used.

As described in the above embodiment, the copper foil has a thickness of 18 μm. So far as the copper foil has a thickness of not less than 8 μm and not more than 25 μm, it causes no failure that the wiring lead is broken due to its insufficient strength and it can be used to form a high-density wiring pattern.

As described in the above embodiment, the ratio (W_{N}/W_{L1}) is in the range more than 0.5 and less than 0.685 where the thickness of the wiring lead 20 is 18 μm. Where the wiring lead 20 has a thickness different from 18 μm, the ratio (W_{N}/W_{L1}) may be set to be a value just before the incidence rate of uncut lead increases steeply.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A tape carrier for semiconductor device, comprising:
a resin tape provided with an opening section for bonding; and
a wiring lead formed on the resin tape,
wherein the wiring lead comprises a notched section disposed in the opening section and including a notch width W_{N}, and a lead width W_{L} at a position where a bonding tool contacts the wiring lead, and
a ratio of the notch width W_{N} to the lead width W_{L} is more than 0.5 and less than 0.685.

2. The tape carrier according to claim 1, wherein:
the notch width W_{N} is determined by the ratio and the lead width W_{L} at a position where a bonding tool contacts the wiring lead.

3. The tape carrier according to claim 1, wherein:
when a lead width W_{L′} of the wiring lead at a position close to a mounting region for a semiconductor device is narrower than the lead width W_{L} at a position where a bonding tool contacts the wiring lead, the notch width W_{N} is determined by the ratio and the lead width W_{L′}.

4. The tape carrier according to claim 1, wherein:
the wiring lead further comprises a thickness of not less than 8 μm and not more than 25 μm.

5. The tape carrier according to claim 1, wherein:
the wiring lead further comprises a thickness of 18 μm.

6. The tape carrier according to claim 1, wherein:
the ratio of the notch width W_{N} to the lead width W_{L} is more than 0.6 and less than 0.685.

7. A method for making a tape carrier for semiconductor device, comprising:
laminating a metal foil on one surface of a resin tape provided with an opening section for bonding; and
forming a wiring lead in the metal foil by photolithography such that the wiring lead comprises a notched section disposed in the opening section and including a notch width W_{N}, and a lead width W_{L} at a position where a bonding tool contacts the wiring lead,
wherein a ratio of the notch width W_{N} to the lead width W_{L} is more than 0.5 and less than 0.685.

8. The method according to claim 7, wherein:
the notch width W_{N} is determined by the ratio and the lead width W_{L} at a position where a bonding tool contacts the wiring lead.

9. The method according to claim 7, wherein:
when a lead width W_{L′} of the wiring lead at a position close to a mounting region for a semiconductor device is narrower than the lead width W_{L} at a position where a bonding tool contacts the wiring lead, the notch width W_{N} is determined by the ratio and the lead width W_{L′}.
s

10. The method according to claim 7, wherein:
the wiring lead further comprises a thickness of not less than 8 μm and less than 25 μm.

11. The method according to claim 7, wherein:
the thickness of the wiring lead is 18 μm.

12. The method according to claim 7, wherein:
the ratio of the notch width W_{N} to the lead width W_{L} is more than 0.6 and less than 0.685.
